(19) United States
(12) Patent Application Publication
(10) Pub. No.: US 2025/0234667 A1
(43) Pub. Date: Jul. 17, 2025

(54) IMAGE SENSING DEVICE INCLUDING PIXEL COORDINATE PATTERN

(71) Applicant: SK hynix Inc., Icheon-si (KR)

(72) Inventor: Sang Jin PARK, Icheon-si (KR)

(21) Appl. No.: 18/959,389

(22) Filed: Nov. 25, 2024

(30) Foreign Application Priority Data
Jan. 17, 2024 (KR) 10-2024-0007627

(51) Int. Cl. H01L 27/146

(52) U.S. Cl. CPC H10F 39/811; H10F 39/182; H10F 39/199

(57) ABSTRACT

An image sensing device including a pixel coordinate pattern representing coordinate values of unit pixels is disclosed. The image sensing device includes a substrate configured to include photoelectric conversion elements, a plurality of conductive lines disposed over a first surface of the substrate, and a plurality of pixel coordinate patterns disposed between the conductive lines to correspond to unit pixels and configured to indicate coordinate values of corresponding unit pixels.

### CROSS-REFERENCE TO RELATED APPLICATION

This patent document claims the priority and benefits of Korean patent application No. 10-2024-0007627, filed on Jan. 17, 2024, which is incorporated by reference in its entirety as part of the disclosure of this patent document.

### TECHNICAL FIELD

The technology and implementations disclosed in this patent document generally relate to an image sensing device including a pixel coordinate pattern representing coordinate values of unit pixels.

### BACKGROUND

Image sensing devices that convert optical images into electrical signals are used in various electronic devices. With the recent development of automotive, medical, computer and communication industries, the demand for highly integrated, higher-performance image sensing devices has been rapidly increasing in various electronic devices such as digital cameras, camcorders, personal communication systems (PCSs), video game consoles, surveillance cameras, medical micro-cameras, robots, etc.

Image sensing devices may be broadly classified into charge coupled device (CCD)-based image sensing devices and complementary metal oxide semiconductor (CMOS)-based image sensing devices. Recently, since an analog control circuit and a digital control circuit can be directly implemented as a single integrated circuit (IC), CMOS-based image sensing devices are being widely used.

### SUMMARY

Various embodiments of the disclosed technology relate to image sensing devices that can more quickly and accurately locate the position of each pixel during a defect analysis (e.g., reverse-engineering) of pixels.

In an embodiment of the disclosed technology, an image sensing device may include a substrate configured to include photoelectric conversion elements, a plurality of conductive lines disposed over a first surface of the substrate, and a plurality of pixel coordinate patterns disposed between the conductive lines to correspond to unit pixels and configured to indicate coordinate values of corresponding unit pixels.

In an embodiment of the disclosed technology, an image sensing device may include a substrate structured to support a plurality of components, the plurality of components include a plurality of unit pixels that include photoelectric conversion elements for sensing light, respectively, a plurality of conductive lines supported by a first surface of the substrate and configured to electrically connect one component of the plurality of components to another component, and a plurality of pixel coordinate patterns disposed between the plurality of conductive lines such that each of the plurality of pixel coordinate patterns corresponds to one of the plurality of unit pixels to indicate coordinate values of one of the plurality of unit pixels.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a schematic diagram illustrating an example structure of an image sensing device based on some implementations of the disclosed technology.

FIG. 2 is a diagram illustrating examples of conductive lines of a metal one (M1) layer formed over a front surface of a substrate in a pixel array of FIG. 1 and pixel coordinate patterns formed between the conductive lines based on some implementations of the disclosed technology.

FIG. 3 is an enlarged view illustrating an example of a unit pixel region in which pixel coordinate patterns of FIG. 2 are formed based on some implementations of the disclosed technology.

FIG. 4 is a cross-sectional view illustrating an example of the unit pixel region taken along the line X-X′ shown in FIG. 3 based on some implementations of the disclosed technology.

FIG. 5 is a diagram illustrating example values assigned to individual patterns of pixel coordinate patterns based on some implementations of the disclosed technology.

FIG. 6 is a diagram illustrating examples of pixel coordinate patterns and non-coordinate patterns.

FIG. 7 is a diagram illustrating examples of pixel coordinate patterns that are formed in units of 100 unit pixels.

FIG. 8 is a diagram illustrating examples of pixel coordinate patterns that are formed for each unit pixel.

FIG. 9 is a diagram illustrating examples of pixel coordinate patterns and coordinate position patterns for use in an 8-shared pixel structure based on some implementations of the disclosed technology.

FIG. 10 is a diagram illustrating example shapes of coordinate position patterns based on some implementations of the disclosed technology.

### DETAILED DESCRIPTION

This patent document provides implementations and examples of an image sensing device including a pixel coordinate pattern that may be used to substantially address one or more technical or engineering issues and mitigate limitations or disadvantages encountered in some other image sensing devices. The disclosed technology can be implemented in some embodiments to provide an image sensing device that can more quickly and accurately locate the position of each pixel during defect analysis of pixels.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

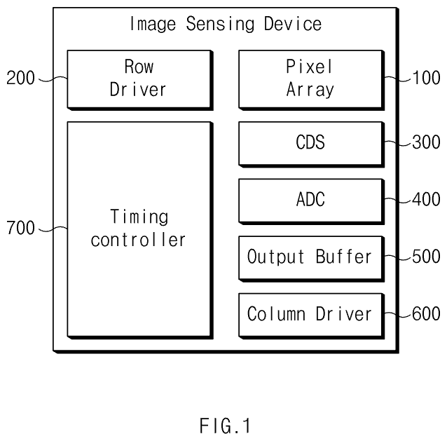

FIG. 1 is a block diagram illustrating an example of an image sensing device based on some implementations of the disclosed technology.

Referring to FIG. 1, the image sensing device may include a pixel array 100, a row driver 200, a correlated double sampler (CDS) 300, an analog-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel array 100 may include a plurality of unit pixels (PXs) consecutively arranged in rows and columns. Each unit pixel (PX) may generate a pixel signal corresponding to incident light through conversion of the incident light. In this case, each unit pixel (PX) may include a photoelectric conversion element for converting incident light into photocharges, and a plurality of pixel transistors for outputting a pixel signal by reading out the photocharges received from the photoelectric conversion element. The plurality of unit pixels may generate a pixel signal on a pixel basis or a pixel group basis, where unit pixels in each pixel group share at least certain internal circuitry (e.g., pixel transistors). For example, a pixel block may include a 4-shared pixel block in which four unit pixels share a floating diffusion (FD) region and pixel transistors or an 8-shared pixel block in which eight unit pixels share a floating diffusion (FD) region and pixel transistors.

The pixel array 100 may receive driving signals (for example, a row selection signal, a reset signal, a transmission (or transfer) signal, etc.) from the row driver 200. Upon receiving the driving signals, the unit pixels may be activated to perform the operations corresponding to the row selection signal, the reset signal, and the transfer signal.

The pixel array 100 may include conductive lines for transmitting driving signals to pixel transistors of unit pixels and transmitting pixel signals generated from the unit pixel. The conductive lines may be formed over a front surface of the substrate when the image sensing device has a back side illumination (BSI) structure in which incident light is received through a back surface of the substrate.

The row driver 200 may activate the pixel array 100 to perform certain operations on the unit pixels in the corresponding row based on control signals provided by controller circuitry such as the timing controller 700. In some implementations, the row driver 200 may select one or more pixel groups arranged in one or more rows of the pixel array 100. The row driver 200 may generate a row selection signal to select one or more rows from among the plurality of rows. The row driver 200 may sequentially enable the reset signal and the transfer signal for the unit pixels arranged in the selected row. The pixel signals generated by the unit pixels arranged in the selected row may be output to the correlated double sampler (CDS) 300.

The correlated double sampler (CDS) 300 may remove undesired offset values of the unit pixels using correlated double sampling. In one example, the correlated double sampler (CDS) 300 may remove the undesired offset values of the unit pixels by comparing output voltages of pixel signals (of the unit pixels) obtained before and after photocharges generated by incident light are accumulated in the sensing node (i.e., a floating diffusion (FD) node). As a result, the CDS 300 may obtain a pixel signal generated only by the incident light without causing noise. In some implementations, upon receiving a clock signal from the timing controller 700, the CDS 300 may sequentially sample and hold voltage levels of the reference signal and the pixel signal, which are provided to each of a plurality of column lines from the pixel array 100. That is, the CDS 300 may sample and hold the voltage levels of the reference signal and the pixel signal which correspond to each of the columns of the pixel array 100. In some implementations, the CDS 300 may transfer the reference signal and the pixel signal of each of the columns as a correlate double sampling (CDS) signal to the ADC 400 based on control signals from the timing controller 700.

The ADC 400 is used to convert analog CDS signals received from the CDS 300 into digital signals. In some implementations, the ADC 400 may be implemented as a ramp-compare type ADC. The analog-to-digital converter (ADC) 400 may compare a ramp signal received from the timing controller 700 with the CDS signal received from the CDS 300, and may thus output a comparison signal indicating the result of comparison between the ramp signal and the CDS signal. The analog-to-digital converter (ADC) 400 may count a level transition time of the comparison signal in response to the ramp signal received from the timing controller 700, and may output a count value indicating the counted level transition time to the output buffer 500.

The output buffer 500 may temporarily store column-based image data provided from the ADC 400 based on control signals of the timing controller 700. The image data received from the ADC 400 may be temporarily stored in the output buffer 500 based on control signals of the timing controller 700. The output buffer 500 may provide an interface to compensate for data rate differences or transmission rate differences between the image sensing device and other devices.

The column driver 600 may select a column of the output buffer 500 upon receiving a control signal from the timing controller 700, and sequentially output the image data, which are temporarily stored in the selected column of the output buffer 500. In some implementations, upon receiving an address signal from the timing controller 700, the column driver 600 may generate a column selection signal based on the address signal, may select a column of the output buffer 500 using the column selection signal, and may control the image data received from the selected column of the output buffer 500 to be output as an output signal.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column. In some implementations, the timing controller 700 may include a logic control circuit, a phase lock loop (PLL) circuit, a timing control circuit, a communication interface circuit and others.

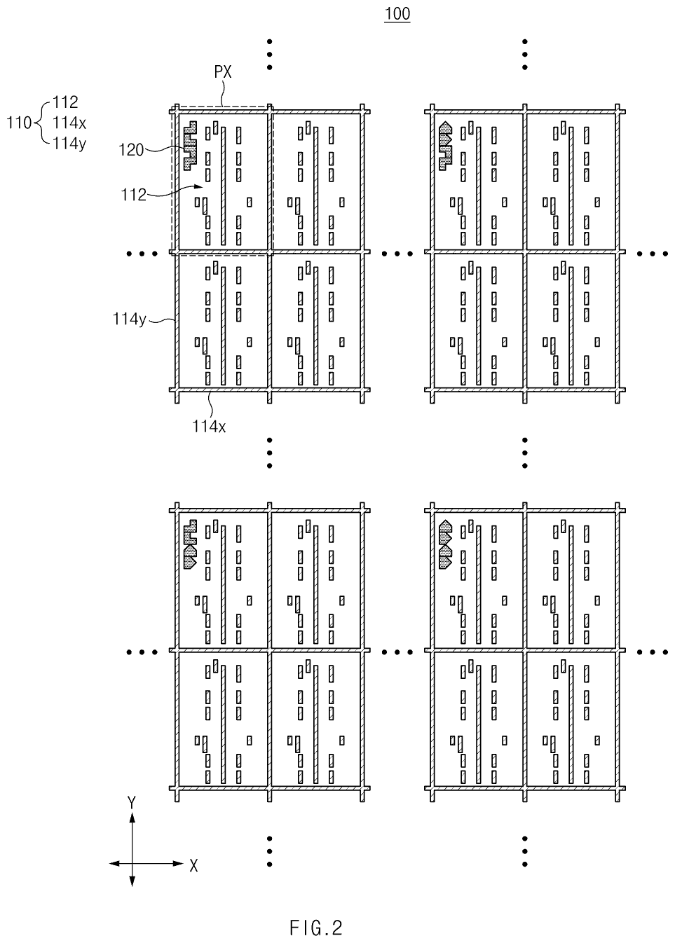

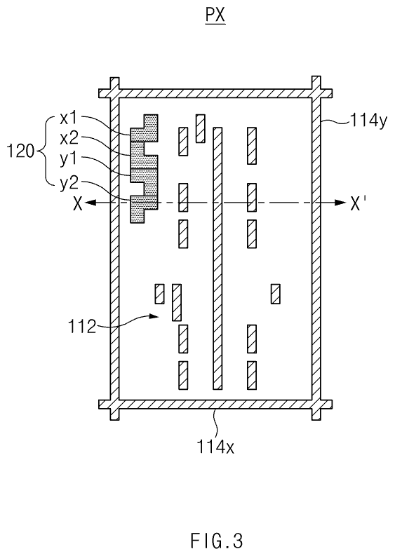

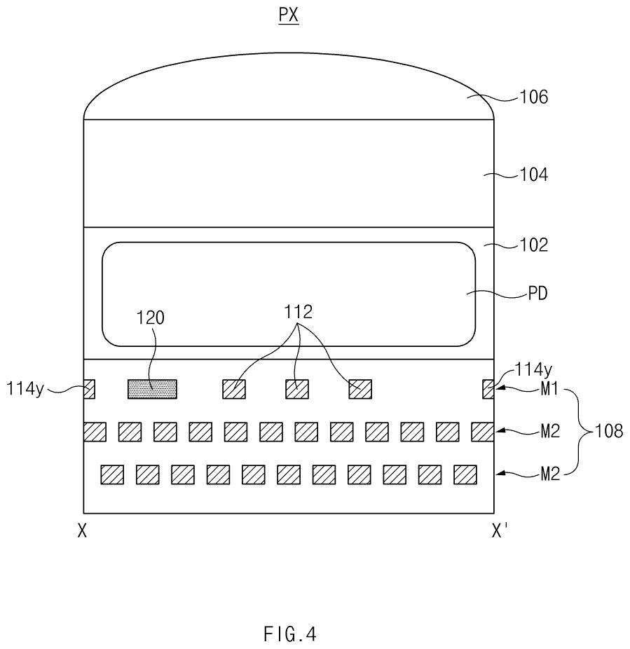

FIG. 2 is a diagram illustrating examples of conductive lines of a metal layer (e.g., “metal one” (M1) layer) formed over a front surface of a substrate in a pixel array of FIG. 1 and pixel coordinate patterns formed between the conductive lines based on some implementations of the disclosed technology. FIG. 3 is an enlarged view illustrating an example of a unit pixel region in which pixel coordinate patterns of FIG. 2 are formed based on some implementations of the disclosed technology. FIG. 4 is a cross-sectional view illustrating an example of the unit pixel region taken along the line X-X′ shown in FIG. 3 based on some implementations of the disclosed technology.

Referring to FIGS. 2 to 4, the pixel array 100 may include conductive lines 110 and pixel coordinate patterns 120.

The conductive lines 110 may be formed over the front surface of the substrate 102 in which photoelectric conversion elements (PD) are formed, and may include conductive lines configured to carry electrical signals between different components. For example, the conductive lines may be used to transmit a driving signal and an operating voltage to the pixel transistors of the unit pixels and to transmit pixel signals generated by the unit pixels. For example, as shown in FIG. 4, in the case of an image sensing device with a back side illumination (BSI) structure in which a color filter 104 and a lens layer 106 are formed over the back surface of the substrate 102, the conductive lines 110 may be formed in an interconnect layer (in some implementations, the interconnect layer may be referred to as a wiring layer) 108 formed over the front surface of the substrate 102. The interconnect layer 108 may include conductive lines formed in each of multi-layer structures (M1, M2, M3). That is, the interconnect layer 108 may include multi-layer structures (M1, M2, M3) composed of conductive lines. The conductive lines 110 based on an embodiment may represent conductive lines formed in a layer (e.g., M1 layer) with many empty spaces between adjacent conductive lines. For example, the conductive line 110 may be formed at a metal layer closest to the substrate 102 among all metal layers of the interconnect layer 108.

The conductive lines 110 may include first and second conductive lines (112, 114x, 114y).

The first conductive lines 112 may include a plurality of conductive lines adjacent to each other and extending in parallel in a second direction. The first conductive lines 112 may be formed as bar-shaped conductive lines separated from each other, and may be formed to correspond to each unit pixel (PX). For example, the first conductive lines 112 may be formed in the same pattern on a pixel basis.

The second conductive lines (114x, 114y) may be located at a boundary region between adjacent unit pixels (PXs), and may be formed to extend in the first direction (e.g., X direction) and the second direction (e.g., Y direction). The second conductive lines (114x, 114y) may be connected to each other, and may be formed to surround the first conductive lines 112.

The pixel coordinate patterns 120 may be formed in empty regions between the conductive lines 110 to correspond to unit pixels in the pixel array 100. For example, the pixel coordinate patterns 120 may be formed in a region defined by the second conductive lines (114x, 114y) in the corresponding unit pixel region.

The pixel coordinate patterns 120 may represent coordinate values that indicate where the corresponding unit pixel is located within the pixel array 100. For example, the pixel coordinate patterns 120 may indicate the order of the corresponding unit pixel located in each of the first direction and the second direction. For example, the pixel coordinate patterns 120 may indicate which position the corresponding unit pixel is located in the first direction and the second direction, respectively. The pixel coordinate patterns 120 may be formed in units of a predetermined number of unit pixels within the pixel array 100. For example, the pixel coordinate patterns 120 may be formed one by one at intervals of 100 unit pixels in each of the first direction and the second direction. Alternatively, the pixel coordinate patterns 120 may be formed to respectively correspond to the unit pixels.

Each pixel coordinate pattern 120 may include a plurality of individual patterns (x1, x2, y1, y2) representing X coordinate values and Y coordinate values. In each pixel coordinate pattern 120, two upper patterns (x1, x2) (corresponding to a value obtained by dividing the total number of individual patterns included in each pixel coordinate pattern by 2) may be patterns representing X coordinate values, and two lower patterns (y1, y2) may be patterns representing Y coordinate values.

Although FIG. 3 shows an example case where the pixel coordinate pattern 120 includes four individual patterns (x1, x2, y1, y2) linearly arranged in the second direction, the disclosed technology is not limited thereto, and it should be noted that the four individual patterns (x1, x2, y1, y2) may also be linearly arranged in the first direction as necessary. In addition, the number of individual patterns included in the pixel coordinate pattern 120 may increase or decrease depending on either the period (or interval) in which the pixel coordinate patterns 120 are formed or the size of the entire pixel array. For convenience of description, an example case where the pixel coordinate pattern 120 includes four individual patterns will be discussed.

In addition, although FIG. 3 shows an example case where the pixel coordinate pattern 120 is formed at the left upper end of the unit pixel region, the disclosed technology is not limited thereto, and it should be noted that the pixel coordinate pattern can be formed anywhere between the conductive lines (112, 114x, 114y). Additionally, the pixel coordinate pattern 120 may be formed in a metal layer other than the M1 layer.

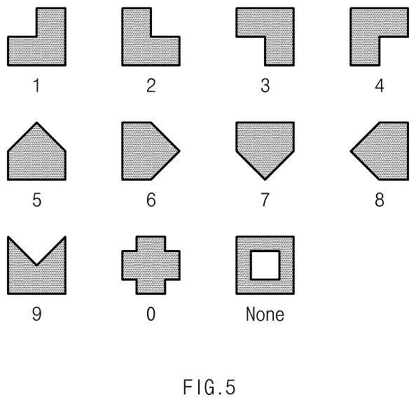

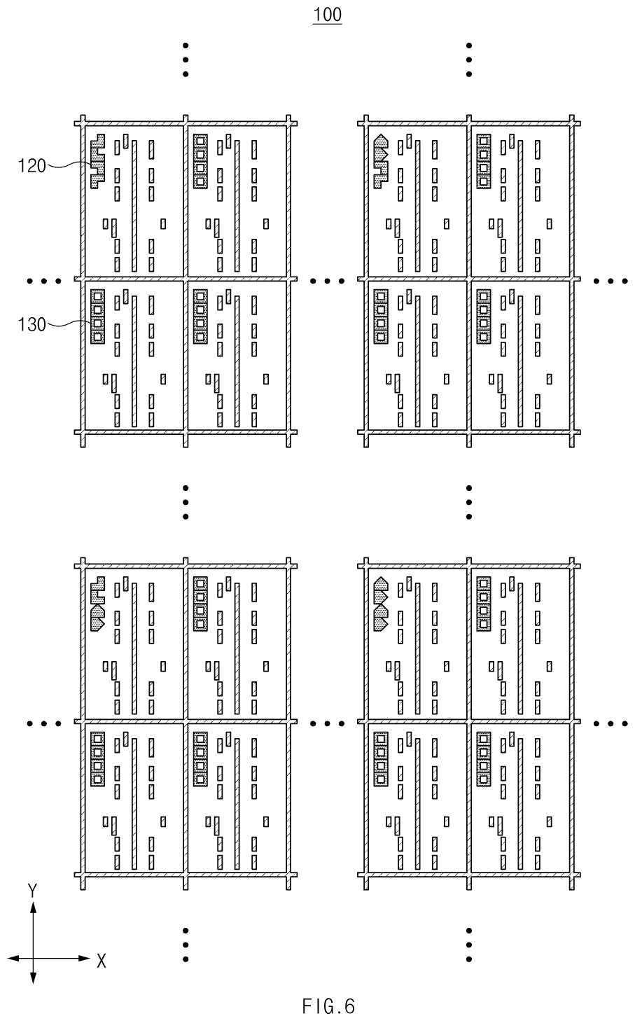

FIG. 5 is a diagram illustrating example values assigned to individual patterns of pixel coordinate patterns based on some implementations of the disclosed technology. FIG. 6 is a diagram illustrating examples of pixel coordinate patterns and non-coordinate patterns.

Referring to FIGS. 5 and 6, one of the values from 0 to 9 is assigned to each individual pattern. For example, in a case where there are ten individual patterns, each of the ten individual patterns can be used to indicate one of the values from 0 to 9 (e.g., a first pattern of the ten individual patterns is used to indicate “0,” a second pattern of the ten individual patterns is used to indicate “1,” . . . , a tenth pattern of the ten individual patterns is used to indicate “9”). In some implementations, the combination of patterns formed on an empty space of a pixel array can be used to indicate a coordinate value to indicate the coordinate or location of a unit pixel corresponding to the combination of patterns on the pixel array. In some implementations, the areas of the individual patterns may have the same size as each other. For example, each of the individual patterns may have a shape in which differently shaped regions of the same size (e.g., ¼ area) are removed from a square of the same size, as shown in FIG. 5. That is, each of the individual patterns may be formed in various shapes having an area of ¾ of a square of the same size. FIG. 5 shows the shapes of the individual patterns by way of example only, and the individual patterns may also be formed in various other shapes as necessary.

Based on the pattern values of FIG. 5, the value indicated by the pixel coordinate pattern shown in FIG. 3 may be denoted by (12, 34). Here, the exact position of the corresponding unit pixel may be determined based on the period (or interval) in which the pixel coordinate pattern is formed. For example, assuming that the pixel coordinate pattern is formed for every 100th unit pixel in each of the first direction and the second direction, the coordinate values indicated by (12, 34) may be denoted by P(1200, 3400). That is, the unit pixel may correspond to a pixel that is located at the 1200th pixel in the first direction and the 3400th pixel in the second direction. If a pixel coordinate pattern is formed for each unit pixel, P(12, 34) may be used as the coordinate values of the corresponding unit pixel.

Individual patterns indicating “None” shown in FIG. 5 may be formed to correspond to unit pixels in which the pixel coordinate patterns 120 are not formed, as shown in FIG. 6. For example, in a unit pixel region where coordinate values are not displayed, no pattern may be formed as shown in FIG. 2 or non-coordinate patterns 130 may be formed as shown in FIG. 6. Like pixel coordinate patterns, the non-coordinate patterns 130 may be formed in a shape in which four individual patterns indicating “None” are linearly arranged in the second direction.

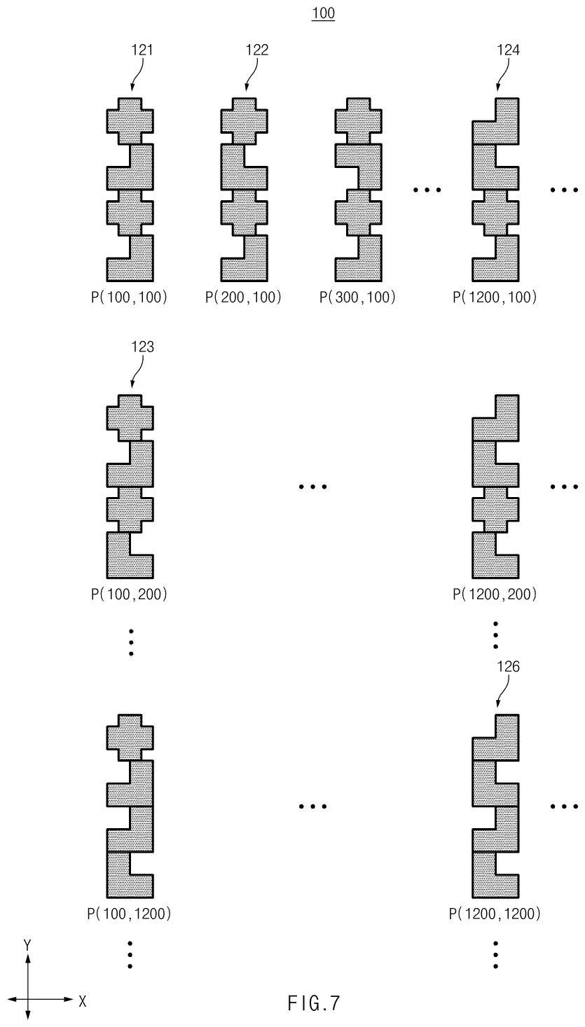

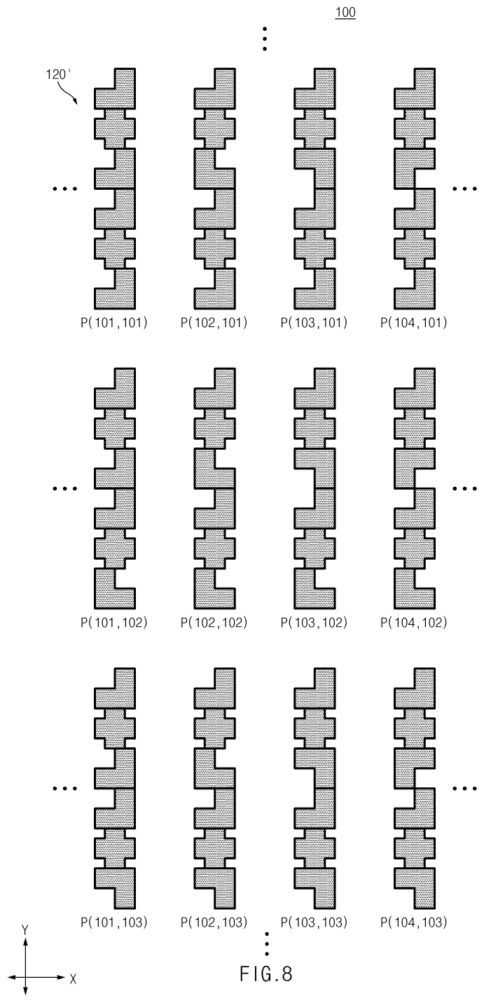

FIG. 7 is a diagram illustrating examples of pixel coordinate patterns that are formed in units of 100 unit pixels. FIG. 8 is a diagram illustrating example states in which pixel coordinate patterns are formed for each unit pixel. For convenience of description, only the pixel coordinate patterns are shown in FIGS. 7 and 8.

Referring to FIG. 7, the pixel coordinate pattern 121 may refer to a pixel coordinate pattern located first in each of the first direction (X direction) and the second direction (Y direction) within the pixel array 100. Accordingly, the unit pixel corresponding to the pixel coordinate pattern 121 is a pixel at a location corresponding to the coordinate values P(100, 100) in the pixel array. That is, the pixel coordinate pattern 121 may indicate that the unit pixel at the position where the pixel coordinate pattern 121 is formed is the 100th pixel in each of the first direction and the second direction.

The pixel coordinate pattern 122 may refer to a pixel coordinate pattern located second in the first direction and first in the second direction within the pixel array 100. Accordingly, the unit pixel corresponding to the pixel coordinate pattern 122 is a pixel at a location corresponding to the coordinate values P(200, 100) in the pixel array. That is, the pixel coordinate pattern 122 may indicate that the unit pixel at the position where the pixel coordinate pattern 122 is formed is the 200th pixel in the first direction and, at the same time, the 100th pixel in the second direction.

The pixel coordinate pattern 123 may refer to a pixel coordinate pattern located first in the first direction and second in the second direction within the pixel array 100. Accordingly, the unit pixel corresponding to the pixel coordinate pattern 123 is a pixel at a location corresponding to the coordinate values P(100, 200) in the pixel array 100. That is, the pixel coordinate pattern 123 may indicate that the unit pixel at the position where the pixel coordinate pattern 123 is formed is the 100th pixel in the first direction and, at the same time, the 200th pixel in the second direction.

Likewise, the pixel coordinate patterns (124, 126) may indicate that the coordinate values of unit pixels at the positions where the pixel coordinate patterns (124, 126) are formed are P(1200, 100) and P(1200, 1200), respectively.

In unit pixel regions where the pixel coordinate patterns (121˜126) are not formed, no patterns may be formed as shown in FIG. 7, or non-coordinate patterns 130 may be formed as shown in FIG. 6.

When performing reverse-engineering for defect analysis, the positions of unit pixels can be confirmed more quickly and accurately through these pixel coordinate patterns.

Referring to FIG. 8, pixel coordinate patterns 120′ may be formed to correspond to the unit pixels, respectively. For example, a pixel coordinate pattern 120′ indicating the position of the corresponding unit pixel may be formed for each unit pixel by increasing the number of individual patterns representing X-coordinate and Y-coordinate values in each pixel coordinate pattern.

In this way, when the pixel coordinate pattern 120′ is formed for each unit pixel, the positions of the unit pixels can be identified more accurately.

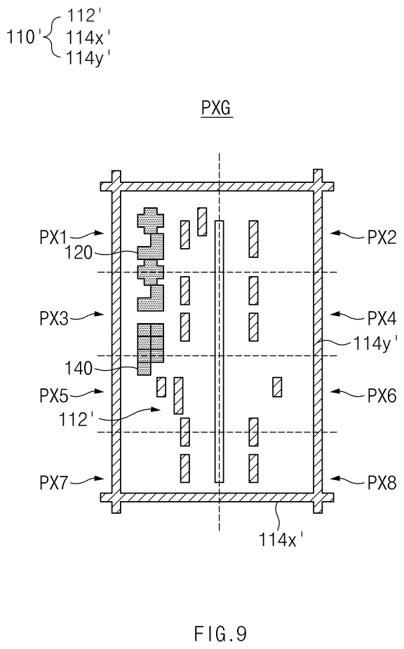

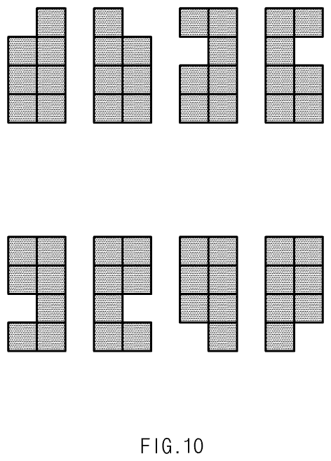

FIG. 9 is a diagram illustrating examples of pixel coordinate patterns and coordinate position patterns for use in an 8-shared pixel structure based on some implementations of the disclosed technology. FIG. 10 is a diagram illustrating example shapes of coordinate position patterns based on some implementations of the disclosed technology.

As discussed above with reference to FIGS. 2 and 3, the first conductive lines 112 may be repeatedly formed in the same pattern on a pixel basis. However, in a structure in which a plurality of unit pixels shares a floating diffusion (FD) region and pixel transistors, the first conductive lines 112′ may be formed repeatedly in units of the plurality of unit pixels corresponding to a pixel group (PXG). For example, in a 4-shared pixel structure or an 8-shared pixel structure, conductive lines formed in the shape shown in FIG. 3 may be formed repeatedly in units of a pixel group (PXG) including 4 unit pixels or 8 unit pixels. FIG. 9 shows an example case where the conductive lines 110′ of the M1 layer are formed in the same shape as in FIG. 3 in units of a pixel group (PXG) including 8 unit pixels.

The pixel array 100 may include conductive lines 110′, a pixel coordinate pattern 120, and a coordinate position pattern 140.

The conductive lines 110′ may include first and second conductive lines (112′, 114x′, 114y′). The first and second conductive lines (112′, 114x′, 114y′) may be formed in the same shape as the first and second conductive lines (112, 114x, 114y) as shown in FIGS. 2 and 3, which are in units of a pixel group (PXG). In addition, in some implementations, the only difference between the pixel coordinate pattern 120 shown in FIG. 9 and the embodiments of FIGS. 2 and 3 is that the pixel coordinate pattern 120 is formed to correspond to the pixel group (PXG). Accordingly, detailed description of the conductive lines 110′ and the pixel coordinate pattern 120 will be omitted here.

The coordinate position pattern 140 may be formed to correspond to the pixel group (PXG) in which the pixel coordinate pattern 120 is formed. For example, the pixel coordinate pattern 120 and the coordinate position pattern 140 may be formed together as a pair in the same pixel group (PXG) region. Although FIG. 9 shows an example case where the coordinate position pattern 140 is located below the pixel coordinate pattern 120, the disclosed technology is not limited thereto, and the coordinate position pattern 140 may be formed anywhere in the empty region between the conductive lines 110′ in the corresponding pixel group (PXG) region.

The coordinate position pattern 140 may indicate which unit pixel among all unit pixels belonging to the corresponding pixel group (PXG) is related to the pixel coordinate pattern 120.

In the 8-shared pixel structure as shown in FIG. 9, one pixel group (PXG) may be divided into eight unit pixel regions (e.g., areas divided by dotted lines) PX1 to PX8. However, since the pixel coordinate pattern 120 is formed in an empty region between the conductive lines 110′, the area where the pixel coordinate pattern 120 is formed and the area of the corresponding unit pixel may not match each other. For example, as can be seen from FIG. 9, the pixel coordinate pattern 120 may be formed to span the area of the unit pixels (PX1, PX3) from the left upper end of the pixel group (PXG). However, the actual pixel coordinate pattern 120 may be, for example, a pattern representing coordinate values of the unit pixel PX8 located at the right lower end of the pixel group (PXG) region. Therefore, the shared pixel structure requires a coordinate position pattern 140 that indicates which unit pixel among unit pixels belonging to the pixel group (PXG) is related to the pixel coordinate pattern 120.

As can be seen from FIG. 10, the coordinate position pattern 140 may be formed in a shape in which any one of the eight individual patterns arranged in the same structure (e.g., a (2x4) structure) as unit pixels (PX1˜PX8) arranged in the pixel group (PXG) is removed. Here, the position of the removed individual pattern among the eight individual patterns may be the position of the unit pixel corresponding to the pixel coordinate pattern 120 in the corresponding pixel group (PXG). The coordinate position pattern 140 shown in FIG. 9 may indicate that the pixel coordinate pattern 120 is a pattern corresponding to the unit pixel PX8 located at the bottom right end among the unit pixels (PX1˜PX8) arranged in a (2×4) structure.

Although FIG. 9 shows only the 8-shared pixel structure for convenience of description, the disclosed technology is not limited thereto, and the coordinate position pattern 140 of the 4-shared pixel structure may also be formed in a shape in which any one of four individual patterns arranged in a (2×2) structure is removed as necessary. The above-described coordinate position pattern 140 can also be applied to a shared pixel structure arranged in another M×N structure (where each of M and N is a natural number of 2 or greater).

As is apparent from the above description, the image sensing device based on some implementations of the disclosed technology can more quickly and accurately confirm the position of each pixel during defect analysis of pixels.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a substrate structured to support a plurality of components, the plurality of components including a plurality of unit pixels that include photoelectric conversion elements for sensing light, respectively;
a plurality of conductive lines supported by a first surface of the substrate and configured to electrically connect one component of the plurality of components to another component; and
a plurality of pixel coordinate patterns disposed between the plurality of conductive lines such that each of the plurality of pixel coordinate patterns corresponds to one of the plurality of unit pixels to indicate coordinate values of one of the plurality of unit pixels.

2. The image sensing device according to claim 1, wherein the pixel coordinate patterns are configured to indicate where the corresponding unit pixels are located in a first direction and a second direction different from the first direction within a pixel array.

3. The image sensing device according to claim 2, wherein:
the pixel coordinate patterns are formed at intervals of a predetermined number of unit pixels in the first direction and the second direction.

4. The image sensing device according to claim 2, wherein:
the pixel coordinate patterns are formed to respectively correspond to the unit pixels.

5. The image sensing device according to claim 1, wherein:
each of the pixel coordinate patterns includes a plurality of individual patterns, wherein each of the plurality of individual patterns is assigned a value corresponding to a value from 0 to 9.

6. The image sensing device according to claim 5, wherein the plurality of individual patterns includes:
a plurality of first individual patterns representing coordinate values for a corresponding unit pixel along a first direction; and
a plurality of second individual patterns representing coordinate values for the corresponding unit pixel along a second direction different from the first direction.

7. The image sensing device according to claim 6, wherein:
the plurality of first individual patterns and the plurality of second individual patterns are arranged in a line.

8. The image sensing device according to claim 5, wherein:
the plurality of individual patterns has a same size as each other.

9. The image sensing device according to claim 8, wherein:
each of the plurality of individual patterns has a shape in which differently shaped regions of a same size are removed from a rectangular shape of a same size.

10. The image sensing device according to claim 1, further comprising:
a plurality of non-coordinate patterns disposed between the plurality of conductive lines to correspond to unit pixels of the plurality of unit pixels in which the pixel coordinate patterns are not formed.

11. The image sensing device according to claim 1, wherein the conductive lines include:
first conductive lines formed in a same pattern for each unit pixel;
and second conductive lines extending in a first direction and a second direction different from the first direction, and surrounding the first conductive lines.

12. The image sensing device according to claim 11, wherein:
each of the pixel coordinate patterns is disposed in a region defined by the second conductive lines.

13. The image sensing device according to claim 1, wherein the conductive lines include:
first conductive lines formed in a same pattern for each pixel group in which a plurality of unit pixels is arranged in an M×N structure, wherein each of M and N is a natural number of 2 or greater; and
second conductive lines extending in a first direction and a second direction different from the first direction, and surrounding the first conductive lines.

14. The image sensing device according to claim 13, further comprising:
a coordinate position pattern formed within a pixel group in which the pixel coordinate pattern is formed and indicating which unit pixel among the plurality of unit pixels belonging to a corresponding pixel group is related to the pixel coordinate pattern.

15. The image sensing device according to claim 14, wherein:
the coordinate position pattern is formed in a shape in which at least one individual pattern corresponding to the position of a unit pixel corresponding to the pixel coordinate pattern from among a plurality of individual patterns arranged in an M×N structure is removed.

16. The image sensing device according to claim 1, wherein:
the pixel coordinate patterns are disposed between one or more conductive lines of a metal layer located closest to the first surface of the substrate from among the plurality of conductive lines.

17. An image sensing device comprising:
a substrate configured to include photoelectric conversion elements;
a plurality of conductive lines disposed over a first surface of the substrate; and
a plurality of pixel coordinate patterns disposed between the conductive lines to correspond to unit pixels and configured to indicate coordinate values of corresponding unit pixels.
